(19) United States
(12) Patent Application Publication
(10) Pub. No.: US 2003/0173678 A1
(43) Pub. Date: Sep. 18, 2003

(54) Semiconductor device and method for fabricating the same

(75) Inventor: Masataka Mizukoshi, Kawasaki (JP)

Correspondence Address: ARMSTRONG,WESTERMAN & HATTORI, LLP, 1725 K STREET, NW, SUITE 1000, WASHINGTON, DC, 20006, US

(73) Assignee: Fujitsu Limited, Kawasaki (JP)

(21) Appl. No.: 10/366,609

(22) Filed: Feb. 14, 2003

(30) Foreign Application Priority Data
Mar. 18, 2002 (JP) 2002-074096

(51) Int. Cl. H01L 23/48

(52) U.S. Cl. 257/774

(57) ABSTRACT

The semiconductor device comprises: a substrate 10 having a through-hole 18 formed therethrough; an electrode 12 formed on one surface of the substrate 10, through-electrode 38 formed in the through-hole 18 and electrically connected to the electrode 12. The through-electrode 38 includes conducting films 26, 32 formed along the inside wall of the through-hole 18, and pin-shaped projection 36 formed on the conducting film exposed on the other surface of the substrate 10. Whereby the pin-shaped projection absorbs stress generated in mounting the semiconductor device, and stable connection can be realized. The pin-shaped projection can be easily formed by plating. A length of the pin-shaped projection can be freely controlled. Accordingly, the through-electrode having the pin-shaped projection can be stably formed without restrictions of shapes and lengths of the hole formed in a substrate.

### CROSS-REFERENCE TO RELATED APPLICATIONS

This application is based upon and claims the benefit of priority from the prior Japanese Patent Application No. 2002-074096, filed in Mar. 18, 2002, the entire contents of which are incorporated herein by reference.

### BACKGROUND OF THE INVENTION

The present invention relates to a semiconductor device and a method for fabricating the same, more specifically a semiconductor device including a through-electrode for electrically connecting a front surface side and a back surface side of a substrate, and a method for fabricating the semiconductor device.

As electronic equipments are required to have higher performance and smaller sizes, densities of inputs/outputs to/from semiconductor devices have been increasingly higher. To this end, the use of CSP (chip size package), wafer-level CSP, etc., which can be smaller-sized are being studied as LSI packages. Composite devices including LSI chips laid in three dimensions for higher densities are also being studied.

To lay LSI chips in three dimensions, electrical connections must be ensured among the vertically arranged LSI chips. To this end, through-electrodes must be formed in the LSI chips for the electrical connection between the front surface sides and the back surface sides.

In a conventional method for forming a through-electrode in an LSI chip, first, a deep hole is formed in the LSI chip by reactive ion etching or laser beam irradiation. Then, an insulating film is formed on the inside surface of the hole by CVD method or others. Next, a metal film is filled by, e.g., sputtering method in the hole with the insulating film formed on. Then, the LSI chip is ground and dry-etched on the back surface side to expose the forward end of the metal film buried in the hole on the back surface side. Thus, through-electrode of the metal film buried in the hole is formed.

However, in the above-described conventional method for forming the through-electrode, the projected portion of the through-electrode beyond the back surface side of the LSI chip does not have a sufficient length. Due to fluctuation of the etching for forming the holes, the projected portions have various lengths. When the projected portions are short and have various lengths, in making the connections through the projected portions, the through-electrodes cannot sufficiently absorb the stress generated when the LSI chip is packaged, which makes it difficult to retain stable electrical connection.

### SUMMARY OF THE INVENTION

An object of the present invention is to provide a semiconductor device including a through-electrode for electrically connecting the front surface side and the back surface side of a substrate and a method for fabricating the semiconductor device, wherein the through-electrode is highly reliable to sufficiently absorb the stress generated in mounting, and the semiconductor device can be stably fabricated.

According to one aspect of the present invention, there is provided a semiconductor device comprising: a substrate having a through-hole formed therethrough; an electrode formed on one surface of the substrate; and a through-electrode formed in the through-hole and electrically connected to the electrode, the through-electrode having a conducting film formed along an inside wall of the through-hole and exposed on the other surface of the substrate, and a pin-shaped projection formed on the conducting film exposed on the other surface of the substrate.

According to another aspect of the present invention, there is provided a method for fabricating a semiconductor device comprising the steps of: forming in an front surface of a substrate a hole which does not reach the back surface of the substrate; forming a conducting film on the front surface of the substrate and in the hole; removing the substrate from the back surface of the substrate until the conducting film is exposed; and forming a pin-shaped projection on the conducting film exposed on the back surface of the substrate.

According to further another aspect of the present invention, there is provided a three-dimensional semiconductor integrated circuit comprising: a plurality of semiconductor devices each including an electrode formed on one surface of a substrate, a conducting film formed along an inside wall of a through-hole formed through the substrate, a pin-shaped projection formed on the conducting film exposed on the other surface of the substrate, and a solder ball provided on the projection, the plurality of semiconductor devices being stacked so that the electrode of each of the semiconductor devices is connected to the solder ball of another one of the semiconductor devices.

As described above, the semiconductor device according to the present invention comprises a substrate, electrode formed on one surface of the substrate, through-hole formed through the substrate, and through-electrode formed in the through-hole and electrically connected to the electrode, in which the through-electrode includes a conducting film formed along the inside wall of the through-hole and exposed on the other surface of the substrate, and a pin-shaped projection formed on the conducting film exposed on the other surface of the substrate. The pin-shaped projection absorbs stress generated in mounting, and stable connection can be realized. The pin-shaped projection can be easily formed by plating. A length of the pin-shaped projection can be freely controlled. Accordingly, the through-electrode having the projection can be stably formed without restrictions of shapes and lengths of the hole formed in a substrate.

### BRIEF DESCRIPTION OF THE DRAWINGS

FIG. 1 is a diagrammatic sectional view of the semiconductor device according to one embodiment of the present invention, which shows a structure thereof.

FIGS. 2A-2C, 3A-3C, 4A-4B, 5A-5C, and 6A-6C are sectional views of the semiconductor device according to the present embodiment in the steps of the method for fabricating the same, which show the method.

FIG. 7 is a view explaining a method for forming the projections of the through-electrodes in the method for fabricating the semiconductor device according to the embodiment of the present invention.

FIGS. 8A-8C are sectional views showing a method for multi-layering the semiconductor devices according to the embodiment of the-present invention.

### DETAILED DESCRIPTION OF THE INVENTION

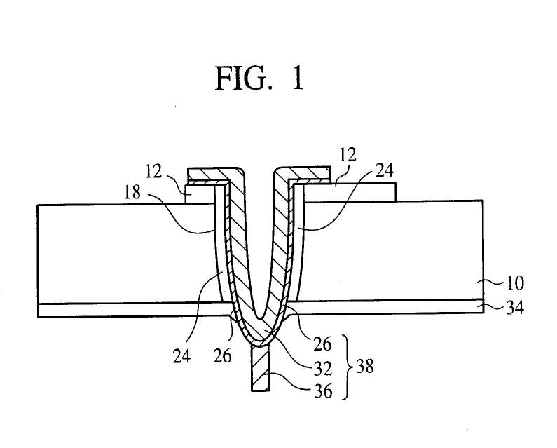

The semiconductor device according to one embodiment of the present invention will be explained with reference to FIGS. 1, 2A-2C, 3A-3C, 4A-4B, 5A-5C, 6A-6C, 7, and 8A-8C.

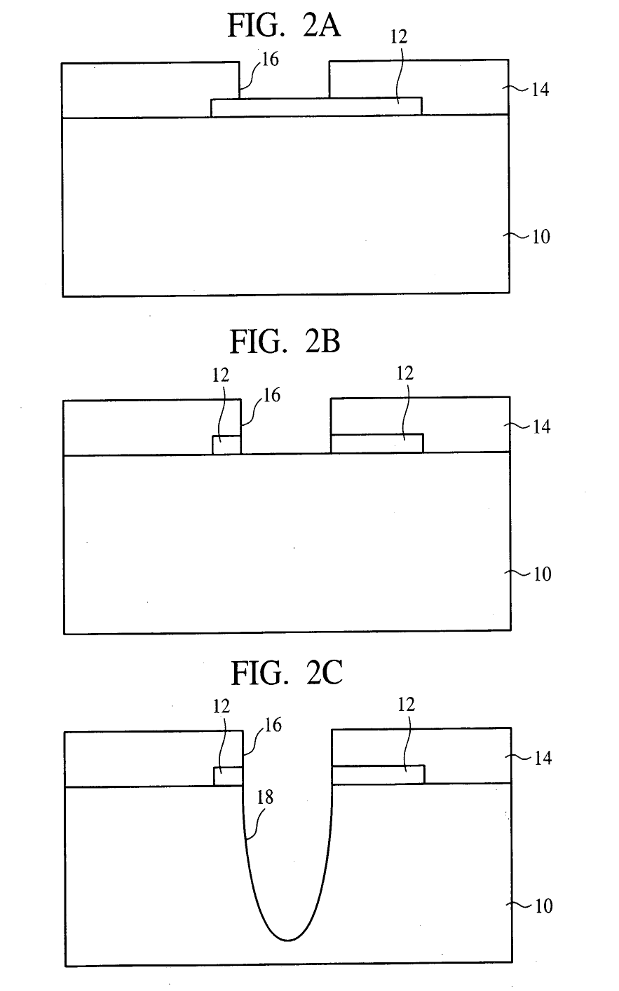

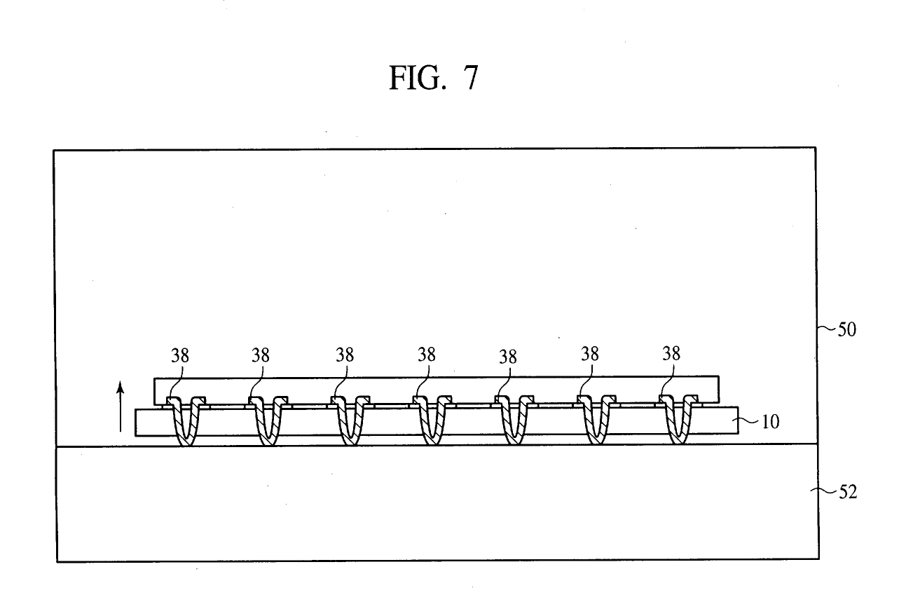

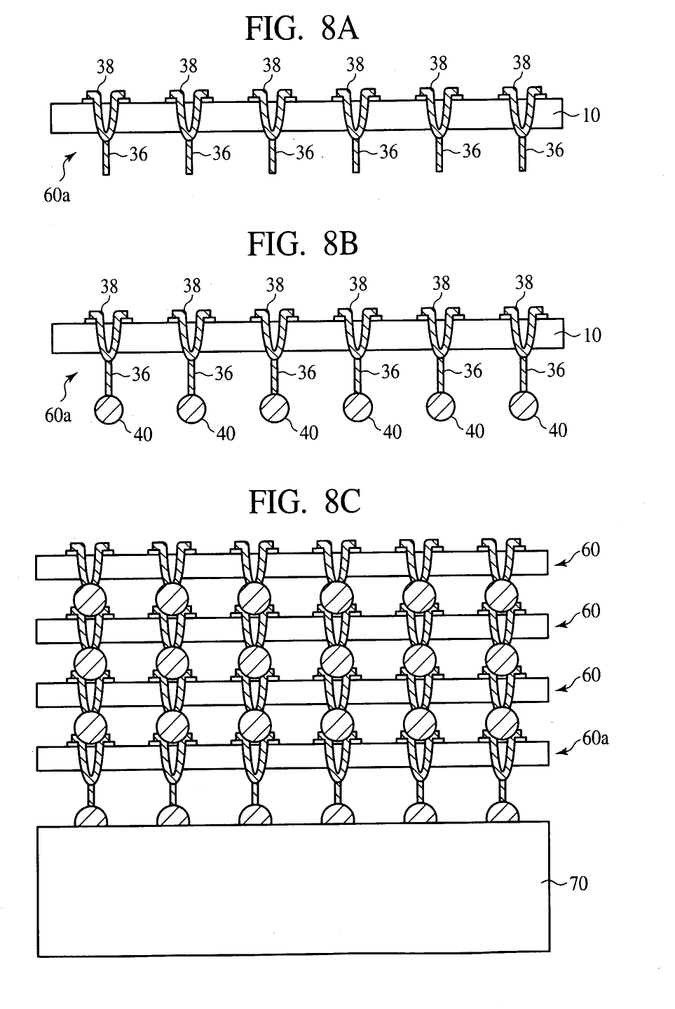

FIG. 1 is a diagrammatic sectional view of the semiconductor device according to the present embodiment, which shows a structure thereof. FIGS. 2A-2C, 3A-3C, 4A-4B, 5A-5C, and 6A-6C are sectional views of the semiconductor device according to the present embodiment in the steps of the method for fabricating the semiconductor device, which show the method. FIG. 7 is a view explaining a method for forming the projections of the through-electrodes in the method for fabricating the semiconductor device according to the embodiment of the present invention. FIGS. 8A-8C are sectional views showing a method for multi-layering the semiconductor device according to the present embodiment.

First, the structure of the semiconductor device according to the present embodiment will be explained with reference to FIG. 1.

An electrode 12 is formed on a substrate 10. The substrate 10 is a semiconductor substrate including semiconductor elements, such as transistors, and passive elements, such as capacitors, inductors, etc. (not shown). The electrode 12 is electrically connected to these elements. An organic insulating film 34 is formed on the back surface of the substrate 10. A Hole 18 down to the back surface of the substrate 10 is formed in the region of the substrate 10 where the electrode 12 is formed. A through-electrode 38 projected beyond the back surface of the substrate 10 and electrically connected to the electrode 12 on the front surface of the substrate is formed in the hole 18. The through-electrode 38 is formed of metal films 26, 32 formed along the inside wall of the hole 18, and a pin-shaped projection 36 formed on the metal film 26 exposed on the back surface of the substrate 10.

As described above, the semiconductor device according to the present embodiment is characterized mainly by the through-electrode 38 having the pin-shaped projection 36 on the back surface side of the substrate 10. The pin-shaped projection 36 provided on the back surface side of the substrate 10 absorbs stress generated in mounting to thereby realize stable connection.

The projection 36 can be easily formed by plating. A length of the projection can be freely controlled. Accordingly, the through-electrode 38 having the projection 36 can be stably formed without being restricted by a shape or a length of the hole 18 formed in the substrate 10.

Then, the method for fabricating the semiconductor device according to the present embodiment will be explained with reference to FIGS. 2A-2C, 3A-3C, 4A-4B, 5A-5C, 6A-6C, and 7.

First, a photoresist film 14 is formed on a substrate 10 by, e.g., spin coating method. The substrate 10 is a semiconductor substrate with semiconductor elements, such as transistors, etc., and passive elements, such as capacitors, inductors, etc., which are not shown, and the electrode 12 is formed on the front surface of the substrate 10, electrically connected to prescribed elements.

Then, an opening 16 for exposing the region where the electrode 12 is formed is formed in the photoresist film 14 (FIG. 2A). The opening 16 is formed in the region for the through-electrode 38 to be formed in.

Next, the electrode 12 exposed in the opening 16 is removed by reactive ion etching with the photoresist film 14 with the opening 16 formed in as a mask (FIG. 2B).

Then, the hole 18 is formed in the substrate 10 in the opening 16 by reactive ion etching or laser beam irradiation with the photoresist film 14 as a mask (FIG. 2C). The hole 18 is, e.g., 50-300 μm deep and is formed in a so-called fire hook shape having an opening diameter decreased along a depth of the substrate 10. A technology for forming the fire hook shaped hole 18 is detained in, e.g., the specification of Japanese Patent Application No. 2002-1738.

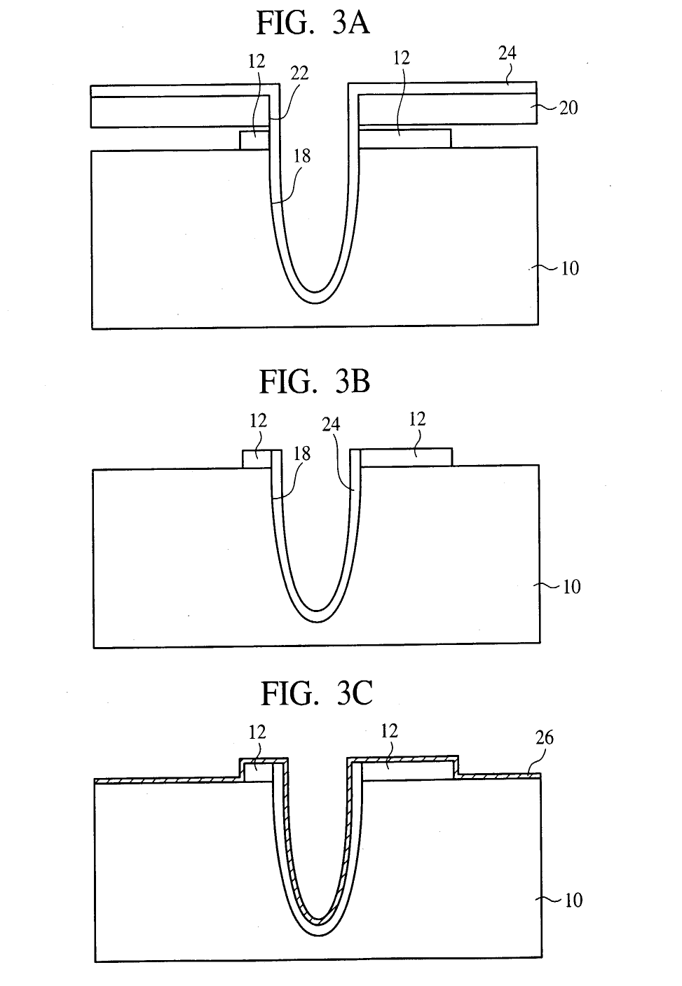

Then, a hard mask 20 with an opening 22 which is positioned over the hole 18 is mounted on the substrate 10. Next, a 20 nm-thick silicon oxide film or silicon nitride film, for example, is deposited by CVD method (FIG. 3A). Then, the hard mask 20 is removed. The insulating film 24 of the silicon oxide film or the silicon nitride film is selectively formed on the inside wall of the hole 18 (FIG. 3B).

This step is not essential when, as described in, e.g., the specification of Japanese Patent No. 2002-1738, the insulating film for covering the inside wall of the hole 18 can be formed concurrently with forming the hole 18.

The hole 18 is not formed essentially in the region where the electrode 12 is formed and may be formed in the region where the electrode 12 is not formed in, e.g., a case that the electrode 12 is formed only for the end of electrically connecting LSI chip formed in an upper layer and LSI chip formed in a lower layer without electrically connecting LSI chip sandwiched therebetween.

Next, a metal film 26 of, e.g., a 20 nm-thick layer film of titanium (Ti) film and palladium (Pd) film is formed on the entire surface by, e.g., sputtering method (FIG. 3C).

It is preferable that the metal film 26 is formed of a layer film of a metal or an alloy having good adhesion with respect to the insulating film 24 and a metal or an alloy having good wettability with respect to solder, or a film of a metal or an alloy having good adhesion with respect to the insulating film 24 and good wettability with respect to solder. Materials having good adhesion with respect to the insulating film 24 of silicon oxide film or others are chrome (Cr), titanium, etc. Materials having good wettability with respect to solder are silver (Ag), gold (Au), copper (Cu), nickel (Ni), palladium, platinum (Pt), etc. Accordingly, the metal film 26 can be, e.g., a layer film of Ti film and Pd film, a layer film of Ti film and Pt film, a layer film of Ti film and Ni film, a layer film of Cr film and Cu film, alloy film of their combinations, etc.

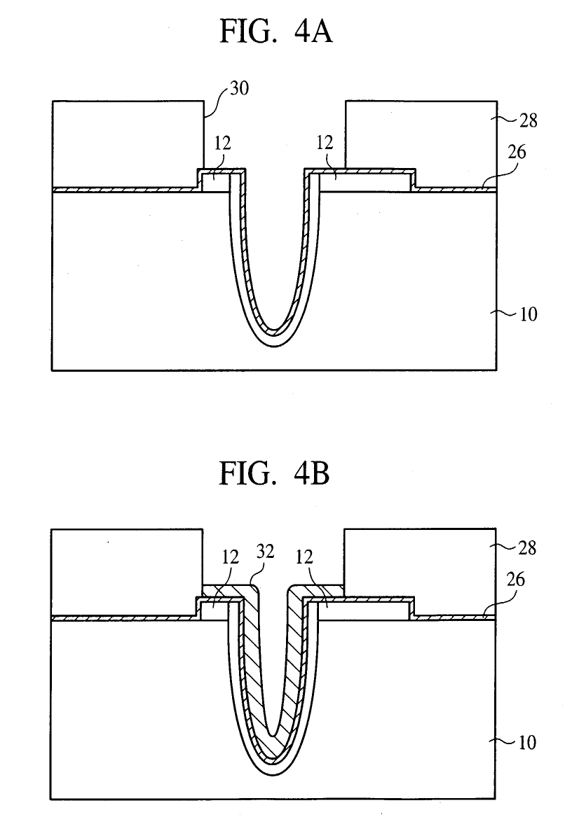

Then, a film resist 28 is adhered to the substrate 10, and exposed and developed to form an opening 30 for exposing the hole 18 and at least a part of the electrode 12 in the film resist 28 (FIG. 4A). The film resist 28 is a photoresist formed in film and has photosensitivity.

Next, a metal film 32 is selectively formed on the metal film 26 in the opening 30 by plating with the metal film 26 as an electrode and a seed layer (FIG. 4B).

A material forming the metal film 32 is preferably selected out of single material or alloy material having good wettability with respect to solder. Materials suitable as the metal film 32 is, e.g., silver, gold, copper, nickel, palladium or platinum, or an alloy of them.

Next, the film resist 28 is removed, and then the substrate is ground from the back surface thereof by grinder up to a position immediately before a position where the ends of the metal films 26, 32 are to be exposed.

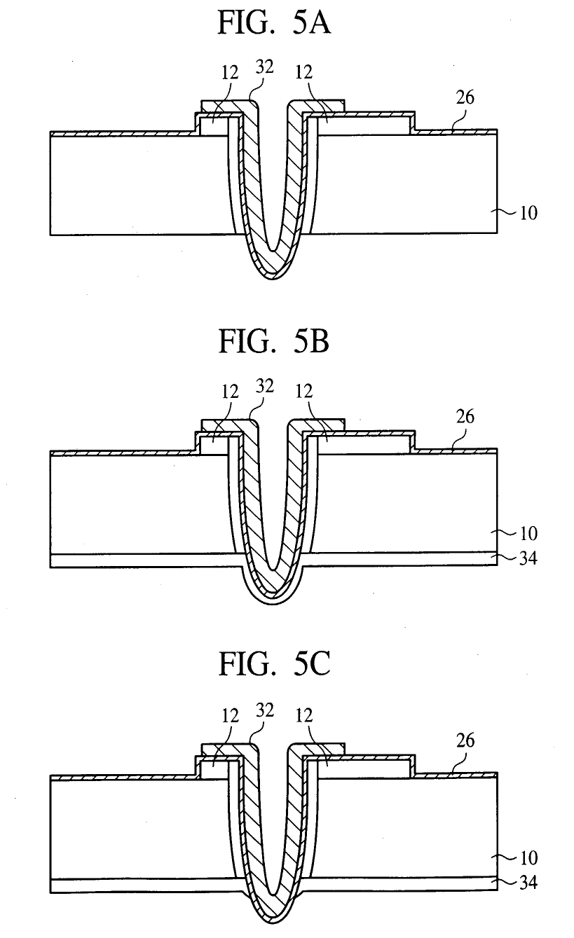

Then, the back surface of the substrate 10 is etched by dry etching using, e.g., a fluorine-based gas until the forward end of the metal films 26, 32 are exposed by about tens μms on the back surface side of the substrate 10 (FIG. 5A).

Next, in a case that the metal film 26 in the region exposed on the back surface side of the substrate has insufficient wettability with respect to solder, the metal film 26 is removed. For example, in the above-described example, the metal film 26 is formed of a layer film of titanium film and palladium film. Titanium film has insufficient wettability with respect to solder, and out of the films forming the metal film 26, the titanium film is selectively removed.

The part of the metal film 26 is removed so that when the projection 36 of a metal having good wettability with solder are formed on the metal film in a later step, the projection 36 can be grown by plating and can have improved adhesion. Accordingly, this step is not essential in a case that the metal film 26 is formed of, e.g., an alloy or others having good adhesion with respect to the insulating film and good wettability with respect to solder, and the projection 36 can be grown by plating and can have sufficient adhesion.

Then, the organic insulating film 34 of, e.g., polyimide is applied to the back surface of the substrate 10 by, e.g., spin coating method. At this time, a viscosity of the application material, and a rotation number are suitably adjusted so that the organic insulating film 34 can be thicker at the plane part and thinner on the metal film 32 (FIG. 5B). For example, a viscosity of the application material is 30 Poise, and a rotation number is 2000 rpm, whereby a film thickness at the plane part is 5 μm, and a film thickness on the metal film 32 is 1 μm.

Next, the organic insulating film 34 is dried and solidified, and then the back surface of the substrate 10 is treated by oxygen plasma. At this time, the organic insulating film 34 on the metal film 32 is thinner than that in the rest region, whereby even after the metal film 32 is exposed, the organic insulating film 34 remains in the rest region (FIG. 5C). In this state, the oxygen plasma treatment is stopped.

Then, the projection 36 is grown on the metal film 26 exposed beyond the back surface of the substrate 10 by plating using the electrode film 26 as an electrode. At this time, as shown in FIG. 7, the projections 36 is set on growing while a distance between a liquid surface of a plating liquid 52 and the substrate 10 is being gradually increasing, whereby the projections 36 can be grown into a pin-shape of, e.g., a 100 μm-length. The projections 36 are thus formed, whereby the projections 36 can be formed in a pin-shape on the metal film 32 without using a mask. A length of the projections 36 is preferably about ½ a size of solder balls to be connected thereto in a later step.

Preferably, a material forming the projections 36 is selected out of materials having the same characteristics as the metal film 26. For example, silver, gold, copper, nickel, palladium or platinum, or their alloy may be used.

In the way of or after the growth of the projections 36, the forward ends of the projections 36 may be ground by a surface grinder of a fine grain to position the heights of the projections 36 on the entire surface on the same level, whereby when the substrate 10 is laid in a multi-layer, the connections can be stable. This method is effective especially in forming the through-electrodes 38 whose projections 36 are long for the direct connection to printed boards.

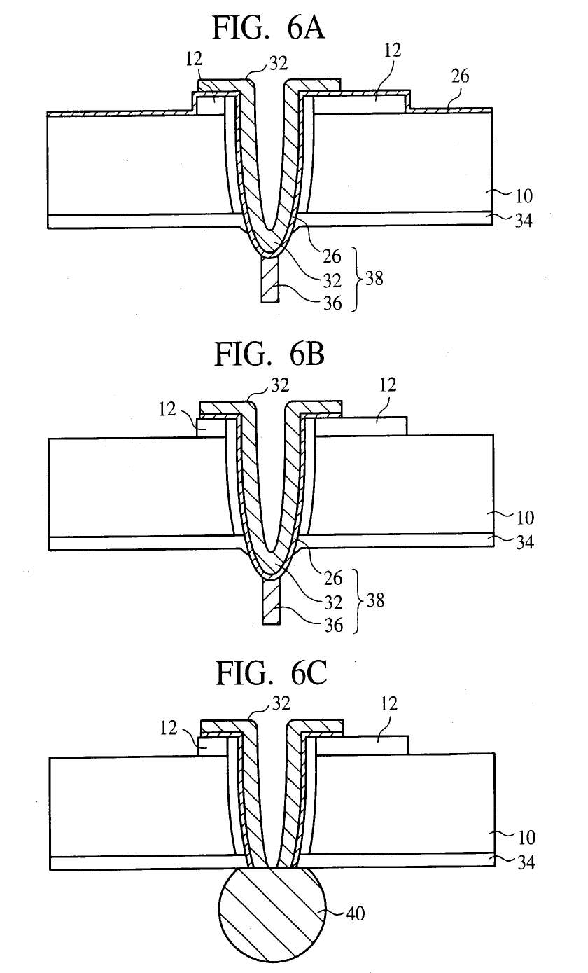

Thus, the through-electrode 38 formed through the substrate 10 and having the metal films 26, 32 and the projection 36 is formed (FIG. 6A).

Next, the metal film 26 is etched from the front surface side of the substrate 10 with the metal film 32 as a mask to electrically separate the through-electrodes 38 from each other (FIG. 6B).

Then, solder ball 40 is pierced into the projection 36 and heated to thereby weld the solder ball 40 to the projection 36 (FIG. 6C).

Thus, the semiconductor device including the through-electrode 38 can be fabricated.

Next, a method for laying on a printed board the semiconductor device including the through-electrodes in a multi-layer will be explained with reference to FIGS. 8A-8C.

A plurality of the semiconductor device 60 including the through-electrodes 38 are prepared by the above described method for fabricating the semiconductor device. At this time, the semiconductor device 60a to be directly connected to a printed board 72 has the projections 36 of, e.g., an about 300 μm-length which is longer than a length of the projections 36 of the other semiconductor devices 60 (FIG. 8A) to weld the solder balls 40 to the forward ends of the projections 36 (FIG. 8B). The length of the projections 36 is made larger, whereby even when a thermal expansion coefficient difference with respect to the printed board is larger, the projections 36 can absorb stress due to the thermal expansion coefficient difference. Thus, the connections can be made stable.

In a case that the through-electrodes 38 having the projections 36 to be directly connected to a printed board 72 are formed, a length of the projections 36 is preferably above 300 μm when a size of the semiconductor device is not less than 5 mm□.

Then, the semiconductor device 60a and a plurality of the semiconductor devices 60 are laid one on another on the printed board 70, and the solder balls 40 are thermally melted to connect the semiconductor devices with one another.

Thus, a plurality of the semiconductor devices 60a, 60 including the through-electrodes 38 can be laid on the printed board 70 in a multi-layer.

As described above, according to the present embodiment, the through-electrode having the pin-shaped projection is formed on the back surface side of a substrate, whereby stresses generated in mounting are absorbed by the projection, and stable connection can be realized. The projection can be easily formed by plating, and a length of the projection can be freely controlled. Accordingly, the through-electrode having the projection can be stably formed without the restrictions of shapes and lengths of the hole formed in a substrate.

What is claimed is:

1. A semiconductor device comprising:
a substrate having a through-hole formed therethrough;
an electrode formed on one surface of the substrate; and
a through-electrode formed in the through-hole and electrically connected to the electrode,
the through-electrode having a conducting film formed along an inside wall of the through-hole and exposed on the other surface of the substrate, and a pin-shaped projection formed on the conducting film exposed on the other surface of the substrate.

2. A semiconductor device according to claim 1, further comprising:
a solder ball provided on the other surface of the substrate, covering the pin-shaped projection.

3. A semiconductor device according to claim 1, further comprising:
a solder ball provided on an end of the pin-shaped projection.

4. A semiconductor device according to claim 1, wherein
the conducting film is provided in contact with the inside wall of the through-hole, and includes a first film of a metal or an alloy adhering to the substrate and a second film formed on the first film and formed of a metal or an alloy which is wettable with respect to a solder.

5. A semiconductor device according to claim 1, wherein
the pin-shaped projection is formed of a metal or an alloy having wettable with respect to a solder.

6. A semiconductor device according to claim 4, wherein
the first film is formed of chrome, titanium or an alloy containing chrome or titanium.

7. A semiconductor device according to claim 4, wherein
the second film is formed of silver, gold, copper, nickel, palladium or their alloy.

8. A semiconductor device according to claim 5, wherein
the pin-shaped projection is formed of silver, gold, copper, nickel, palladium or their alloy.

9. A semiconductor device according to claim 1, which comprises a plurality of the through-electrodes, and in which heights of said a plurality of the pin-shaped projections are substantially the same.

10. A method for fabricating a semiconductor device comprising the steps of:
forming in an front surface of a substrate a hole which does not reach the back surface of the substrate;
forming a conducting film on the front surface of the substrate and in the hole;
removing the substrate from the back surface of the substrate until the conducting film is exposed; and
forming a pin-shaped projection on the conducting film exposed on the back surface of the substrate.

11. A method for fabricating a semiconductor device according to claim 10, wherein
in the step of forming the pin-shaped projection, a the pin-shaped projection is formed by growing a metal or an alloy on the conducting film by plating while a distance between a liquid surface of a plating liquid and the substrate is being gradually increased.

12. A method for fabricating a semiconductor device according to claim 10, wherein
in the step of forming the hole, the hole is formed in a shape having an opening width increased toward the front surface of the substrate.

13. A method for fabricating a semiconductor device according to claim 10, further comprising the step of:
grinding ends of the pin-shaped projections in the way of or after forming the pin-shaped projection to thereby position heights of a plurality of the pin-shaped projections on the same level.

14. A method for fabricating a semiconductor device according to claim 10, wherein
in the step of forming the conducting film, the conducting film is formed of a first conducting film of a material which adheres to the substrate and a second conducting film of a material which is wettable with respect to a solder, and
in the step of forming the pin-shaped projection, the first conducting film exposed on the back surface of the substrate is removed, and then the pin-shaped projection is formed on the second conducting film.

15. A three-dimensional semiconductor integrated circuit comprising: a plurality of semiconductor devices each including an electrode formed on one surface of a substrate, a conducting film formed along an inside wall of a through-hole formed through the substrate, a pin-shaped projection formed on the conducting film exposed on the other surface of the substrate, and a solder ball provided on the pin-shaped projection,
the plurality of semiconductor devices being stacked so that the electrode of each of the semiconductor devices is connected to the solder ball of another one of the semiconductor devices.

16. A three-dimensional semiconductor integrated circuit according to claim 15, wherein
the plurality of semiconductor devices are mounted on a printed board, and
a length of the pin-shaped projection of one of the semiconductor devices directly connected to the printed board is larger than a length of the pin-shaped projections of the other semiconductor devices.
